(19) United States
(12) Patent Application Publication
(10) Pub. No.: US 2003/0025553 A1
(43) Pub. Date: Feb. 6, 2003

(54) Resource managed power amplifier

(76) Inventor: Alan E. Faris, Los Angeles, CA (US)

Correspondence Address: Patent Counsel, TRW Inc., S&E Law Department, E2/6051, One Space Park, Redondo Beach, CA, 90278, US

(21) Appl. No.: 09/921,833

(22) Filed: Aug. 3, 2001

(51) Int. Cl. H03F 1/14; H03F 3/68

(52) U.S. Cl. 330/51; 330/124 R

(57) ABSTRACT

The preferred embodiments of the present invention provide a resource managed power amplifier. The resource managed power amplifier is dynamically configurable. The amplifier includes a switching unit for routing an input signal to at least one of a plurality of amplifier cells. Preferably, the switching unit routes the input signal in response to at least one input selector. The amplifier also includes a plurality of amplifier cells amplifying the input signal to produce an amplified signal.

### BACKGROUND OF THE INVENTION

The present invention relates generally to a power amplifier. More specifically, the present invention relates to a resource managed power amplifier wherein inputs to the power amplifier may be dynamically allocated among a plurality of amplifier cells for dynamic amplification.

Modern electrical equipment, such as cellular phones, stereo systems, satellites, radios, and other such electronics, for example, process electrical signals to produce a desired result, such as stereo sound or wireless communication, for example. The electrical signals used by electrical equipment may be originally generated at a variety of signal strengths. Amplifiers are used in electronics to increase the strength of weaker input signals to form stronger output signals that are more reliable for processing in electrical equipment. For example, an amplifier may amplify a microvolt (iV) or millivolt (mV) signal to a volt (V) signal. Using an amplifier, an output signal may be created that is a copy of the input signal at an increased signal strength level.

One type of amplifier is a power amplifier. In a power amplifier, the electrical current of the signal is amplified with some additional gain in voltage. While the power amplifier may receive little power at the input, using a power transistor the power amplifier may deliver large amounts of power to the output.

Power amplifiers are typically employed any time a communications signal is transmitted. For example, power amplifiers may be used in stereo systems to provide sufficient power to drive loudspeakers in a stereo system, for example. A linear power amplifier may replicate both soft and loud sounds with minimal distortion. Additionally, power amplifiers may also be used in the cellular phone industry. For example, power amplifiers may be used in cellular phone handsets to amplify communication signals emitted by the handset and transmitted by the handset. Additionally, power amplifiers may be used in cellular phone towers to amplify signals received from cellular handsets or other cellular towers, for example, and also to amplify signals transmitted to cellular handsets or other cellular towers. Power amplifiers may also be used with satellites to amplify signals transmitted to and from satellites.

Currently, power amplifiers may be packaged in large arrays of power transistors. A power transistor typically includes three terminals: a base, an emitter, and a collector. The three terminals are connected to three regions of semiconductor material that form the transistor. A difference in voltage between two of the three terminals controls current through the third terminal. In power transistor arrays, the collectors of the power transistors are typically tied together to form the output of the power amplifier. Additionally, in the power transistor arrays, the bases are summed together to form the input of the power amplifier. That is, currently, the output and input lines of power amplifiers are fixed in a predefined configuration. No dynamically configurable power transistor array currently exists. A fixed, predefined amplifier configuration does not allow for variation in the number of signal inputs to the power amplifier. Additionally, a fixed configuration does not allow for a shifting of amplifier resources based on input demand. Thus, there is a need for power amplifiers with flexible, dynamically adjustable input configurations.

Additionally, in systems requiring variable amounts of power, such as cellular phone networks, for example, large power amplifier arrays must be designed to accommodate the greatest possible power use in the system. That is, if a transmitter may use 1000 W (Watts) of power but commonly only uses 200 W, the transmitter employs a 1000 W power amplifier, typically resulting in an simple mathematic excess expenditure of 800 W of power. Additionally, because a power amplifier operates at approximately 35% efficiency, the actual excess power needed to generate the mathematical excess power of 800 W is approximately 2,285 W of actual power (800 W * 1/0.35=2,285W). Excess power consumption may result in reduced battery life, for example. Additionally, excess power dissipation generates heat that may damage equipment or result in higher equipment cost to provide for heat absorption. Additionally, because the system is hardwired, the power amplifier is limited to a predetermined configuration. A predetermined configuration may result in wasted power and additional system expense. Currently, no system exists that provides the benefit of adapting to users' differing power requirements. Thus, there is a need for a scalable, efficient power amplifier that adapts to the power demands of its current users.

Thus, a need has long been felt for an adaptable power amplifier that is not limited to a pre-determined amplification value. A need has especially been felt for a flexible power amplifier whose resources and configuration are not predetermined and may be matched to system demand.

### SUMMARY OF THE INVENTION

The preferred embodiments of the present invention provide a resource managed power amplifier. The resource managed power amplifier is dynamically configurable. The amplifier includes a switching unit for routing an input signal to at least one of a plurality of amplifier cells. Preferably, the switching unit routes the input signal in response to at least one input selector. The amplifier also includes a plurality of amplifier cells amplifying the input signal to produce an amplified signal. In a preferred embodiment, the switching unit may route the input signal to more than one amplifier cell based on an input selector corresponding to the desired power level of the signal. In an alternative embodiment, the switching unit may route a plurality of input signals to the plurality of amplifier cells for signal amplification. In a preferred embodiment, the amplifier also includes an output for transmitting the amplified signal or amplified signals. The amplified signals may be transmitted individually or combined. The preferred method includes receiving the input signal, routing the input signal to at least one amplifier according to the input selector, and amplifying the signal using the amplifiers to produce an amplified signal.

### BRIEF DESCRIPTION OF THE DRAWINGS

FIG. 1 illustrates a resource managed power amplifier system according to a preferred embodiment of the present invention.

FIG. 2 illustrates one embodiment of a resource managed power amplifier system.

FIG. 3 illustrates another embodiment of a resource managed power amplifier system.

FIG. 4 illustrates another embodiment of a resource managed power amplifier system.

FIG. 5 illustrates another embodiment of a resource managed power amplifier system.

FIG. 6 illustrates a flowchart for dynamically routing inputs to outputs in a power amplifier.

### DETAILED DESCRIPTION OF THE PREFERRED EMBODIMENT

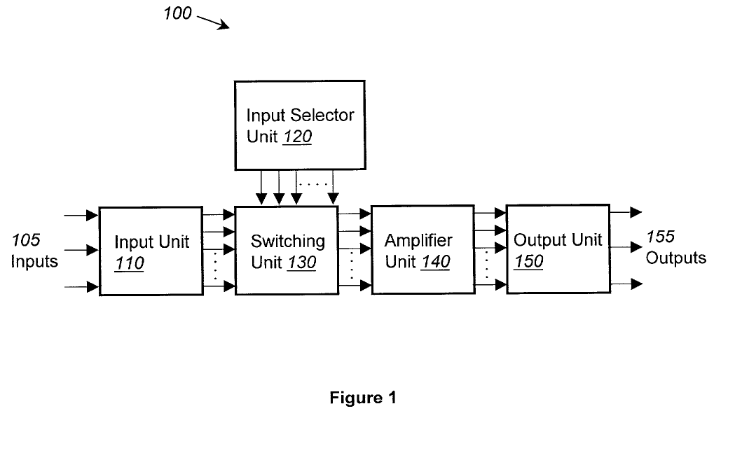

The preferred embodiments of the present invention provide a flexible, dynamically adjustable, efficient framework for signal power amplification. FIG. 1 illustrates a resource managed power amplifier system 100 according to a preferred embodiment of the present invention. The resource managed power amplifier system 100 includes at least one input signal 105, an input unit 110, an input selector unit 120, a switching unit 130, an amplifier unit 140, an output unit 150, and at least one output signal 155.

In a preferred embodiment, the input unit 110 includes at least one input 105 for receiving at least one signal from an electronic device, such as cellular phones, cellular towers, stereo systems, satellite systems, optical systems, and other such electronic equipment, for example. For the purposes of illustration only, the following description will use the example of a cellular phone system. The input unit 110 is preferably connected to the switching unit 130. Preferably, the switching unit 130 includes at least one connection to connect the input 105 from the input unit 1 10 to the amplifier unit 140. The switching unit 130 is controlled by the input selector unit 120 that determines the routing configuration of inputs 105 from the input unit w 110 to the amplifier unit 140. Preferably, the amplifier unit 140 includes a plurality of amplifier cells that each amplify signals. Preferably, an input signal 105 may be routed to one or more amplifier cells for amplification, depending on the desired output power level of the signal. Additionally, multiple input signals 105 may be routed among multiple amplifier cells for signal amplification. The configuration of the switching unit 130 may depend on the number of input signals 105 and the desired output power of the input signal(s). The outputs of the amplifier cells in the amplifier unit 140 are connected to the output unit 150. The output unit 150 combines one or more amplifier outputs to form the managed amplifier output 155.

As further described below, once a signal is received at the input unit 110, the signal is relayed to the switching unit 130. The switching unit 130 also receives input selectors from the input selector unit 120 based on a measurement of the input signal strength or another external indicator, for example. The input selector unit 120 directs the switching unit 130 to route the signal received at the switching unit 130 to at least one amplifier cell in the amplifier unit 140. The outputs of the amplifier unit 140 are sent to the output unit 150 to be combined.

Preferably, the input unit 110 receives at least one signal 105 to be amplified. The input unit 1 10 may receive signals from electronic devices, as described above, for example. For example, the input signal 105 may be received from electronic devices using variable frequencies or channels. Also, for example, the input signal 105 may be received from electronic devices at variable strength levels. The input unit 110 may receive signals through wire-based receivers, wireless receivers, optical receivers or other such signal transmission receivers, for example.

In a preferred embodiment, the input unit 110 includes at least one input to receive the signal for amplification. Alternatively, multiple signals or bands (frequency bands and/or time bands, for example) may be contained in each of a plurality of inputs received at the input unit 110.

In a preferred embodiment, the input selector unit 120 includes a processor that selects which inputs to connect to which amplifier cells using the switching unit 130. The input selector unit 120 may include a computer and/or software, for example, that monitor the input signals and determine which inputs to connect which outputs based on signal strength, power requirements, signal load, or another external indicator, for example. Preferably, the input selector unit 120 may dynamically determine which inputs 105 should be connected to which amplifier cells on the basis of desired transmission strength, for example. That is, if signal strengths or system power requirements change during operation, the input selector unit 120 may alter the configuration of the switching unit 130 to account for the changing requirements. In an alternative embodiment, the input selector unit 120 may include external selectors to route inputs to amplifier cells. For example, input selectors may be transmitted using the Internet, a satellite, or a base station, for example. Alternatively, a network control center may perform a remote analysis of the input signal and transmit input selectors to the switching unit 130.

Preferably, the switching unit 130 connects inputs from the input unit 110 to the amplifier unit 140 based on input select information from the input selector unit 120. Preferably, the connections are made using wires, for example, to link the inputs with the amplifier cells of the amplifier unit 140. Alternatively, the connections may be made with wireless connections, optical connections, or other such connections, for example. Preferably, the switching unit 130 also includes a power source to provide bias voltages to the amplifier unit 140 to power on or power off amplifier cells in the amplifier unit 140. In order to activate amplifier cells in the amplifier 140, the switching unit 130 applies a bias voltage to the desired amplifier cells. That is, switches are closed to connect the power source to the desired amplifier cells, thus enabling or turning on the amplifier cells.

Biased amplifier cells are turned on for power amplification. Amplifier cells without bias thus consume no power and are turned off resulting in significant power savings. Preferably, the system 100 only activates the amplifier cells used to produce the desired power amplification and, thus, saves power. Preferably, the power consumption of the system 100 is improved, leading, for example, to improved battery life. Additionally, power sources may be smaller and/or less expensive because the system 100 is more efficient due to dynamic activation of amplifier cells. Furthermore, the elimination of excess power dissipation by turning off unused amplifier cells may reduce the use and/or number of cooling fans or heat sinks in systems.

In most systems, the time for an amplifier cell to power up is well within the time frame to amplify the received signal. Alternatively, in systems with a shorter amplification time frame, additional amplifier cells may be used to help ensure that power available exceeds power demand. For example, the system may activate amplifier cells equivalent to 105% of demand.

In a preferred embodiment, the amplifier unit 140 includes a plurality of amplifier cells to amplify the input signals. Preferably, the amplifier cells include power transistors amplifying the power of the input signals. The amplifier cells preferably include transistors capable of amplifying the current and/or the voltage of the input signals, for example. The power transistors may be any of a variety of power transistors widely known in the art. For example, the power transistor may be a bipolar junction transistors (BJTs), or a field-effect transistors (FETs), such as the metal-oxide semiconductor field-effect transistor (MOSFET) or double diffused MOSFET (DMOSFET), for example.

Preferably, the inputs from the switching unit 130 are fed into the amplifier cells of the amplifier unit 140. Preferably, the amplifier cells are powered by the switching unit 130, as described above. Then, preferably, the power transistors in the amplifier cells amplify the power of the signals received from the inputs by amplifying the power of the input signal. Preferably, the outputs of the amplifier cells in the amplifier unit 140 are connected to the output unit 150. The amplifier cell outputs are preferably connected to the output unit 150 by wires, for example. The amplifier cell outputs may also be connected to the output unit 150 by wireless connections, optical connections, or other such connections, for example.

The output unit 150 receives the amplified signals from the amplifier unit 140 and combines the amplified signals. The output signals may be transmitted individually or the output signals may be summed as one output signal. For example, as further discussed below, an input signal may be routed to two amplifier cells for amplification. Then, for example, the outputs of the two amplifier cells are summed to produce the amplified output of the input signal. Additionally, a plurality of amplified signals at different frequencies may be combined into one output signal (a time division multiple access (TDMA) signal, a multiple frequency signal, and/or a code division multiple access (CDMA) signal for example). The number of outputs from the output unit 150 may or may not equal the number of inputs to the input unit 110.

In operation, the input unit 110 receives signals from an external electronic device, as discussed above. For example, receivers at the input unit 110 of a cellular tower receive signals from several cellular phones in the service area. Then, the input unit 110 relays the received signals to the switching unit 130. The input selector unit 120 determines which signals to connect to which amplifier cells in the amplifier unit 140 via the switching unit 130. For example, the incoming signals are analyzed on the basis of desired power level and/or input power to determine the desired amplification for each signal. For example, one input may be destined for a distant cellular phone and require more output power, while a second signal may be destined for a nearer cellular phone and require less output power. The first signal thus requires more amplifier cells to produce greater output power.

Preferably, different amplifier cells may provide different levels of power amplification, for example, the amplifier cells may be binary weighted. Alternately, each amplifier cell provides the same power amplification. Based on power information from the input selector unit 120, the switching unit 130 routes the input from the input unit 110 to amplifier cells in the amplifier unit 140. The input may be routed to one or more amplifier cells in the amplifier unit 140 to meet the desired power level.

For example, signals destined for a greater range receive a correspondingly greater number of amplifier cells. For example, a cellular phone signal travelling a great distance from a cellular tower will be allocated a greater number of amplifier cells than a cellular phone signal travelling a short distance from a cellular tower. That is, a cellular phone signal transmitted several miles from a cellular tower may require more power (due to signal degradation) to reach the cellular tower than a cellular phone signal travelling a shorter distance. Thus, for example, the more distant cell phone requires more output power than then cellular phone signal transmitted a shorter distance from the cellular tower.

Because amplifier resources are preferably dynamically activated as needed, amplifier cells are not always turned on. Therefore, amplifier cells must be turned on before the input is routed to the amplifier cells(s). Preferably, power is applied to activate the desired amplifier cells in the amplifier unit 140. That is, switches in the switching unit 130 are closed to apply bias voltages to desired amplifier cells in the amplifier unit 140 to activate the amplifier cells. The total number of amplifier cells activated in the amplifier unit 140 may vary depending on the total output power to be provided by the amplifier unit 140.

Next, the amplifier unit 140 amplifies the input signal routed from the switching unit 130. That is, amplifier cells in the amplifier unit 140 increase the power of the input signals by passing the input signal through at least one power transistor, such as a BJT or a MOSFET, for example. The power transistors amplify the signal. Preferably, the input signal travels to the input of the power transistor. Power is externally applied to the power transistor. The signal interacts with the power at the power transistor, and the signal is amplified. Then, the amplified output signal is preferably emitted from the output of the power transistor. The power of the signal is increased according to the power gain (Aₚ) of the amplifier, such that the output power (P_{O}) equals the input power (Pᵢ) multiplied by the amplifier power gain (P_{O}=PᵢAₚ).

Then, the amplified signal is transmitted from the amplifier unit 140 to the output unit 150. Preferably, the amplified signal is transmitted via wires, for example, from the output of the power transistor to the input of the output unit 150. Finally, the output unit 150 transmits the amplified signal via an attached antenna unit. Preferably, the amplified signals are broadcast using wireless antennas, for example. For example, the amplified signals are transmitted from the cellular tower to cellular phones via antennas at the cellular tower. Alternatively, the amplified signals may be transmitted over wires, optical transmitters, or other transmission media, for example. That is, the amplified signals are transmitted, via wireless transmitter, wire transmitter, optical transmitter, or other such transmitter, for example, to an electronic device for use or further processing.

An input may be connected to multiple amplifier cells by the switching unit 130. The input may be amplified by each amplifier cell. Then, the amplified signals are added to produce one amplified signal by the output unit 150. Additionally, the input unit 110 may receive a plurality of signals that are routed to a plurality of amplified cells by the switching unit 130 and connected to a plurality of outputs in the output unit 150. The plurality of signals may be combined and output together. The plurality of signals may also be output separately.

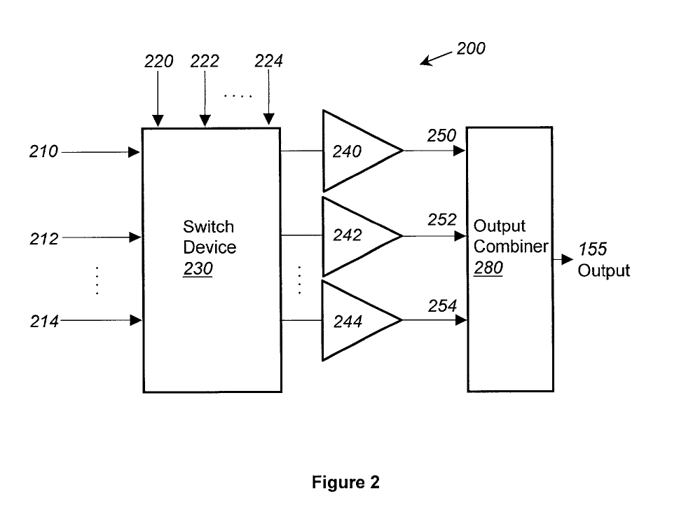

FIG. 2 illustrates one embodiment of a resource managed power amplifier system 200. FIG. 2 may be representative of a cellular phone tower, for example. The system 200 is substantially similar to the resource managed power amplifier system 100 described in reference to FIG. 1. The system 200 includes inputs 210, 212, 214, input selects 220, 222, 224, a switch device 230, amplifiers 240, 242, 244, outputs 250, 252, 254, an output combiner 280, and summed output 255. The subsystems of the system 200 are substantially similar to the corresponding subsystems of the system 100 described above.

The inputs 210, 212, 214 may be cellular phone signals. The cellular phone signals may be routed to one or more amplifiers 240, 242, 244 by the switch device 230 using the input selects 220, 222, 224 as described above. The input selects 220, 222, 224 may be triggered based on signal load (such as the number of users, for example) and/or the desired power level of the transmitted signal. The input cellular phone signals are amplified by the amplifiers 240, 242, 244 and transmitted by the outputs 250, 252, 254, as described above.

Additionally, the outputs 250, 252, 254 may be summed by the output combiner. That is, the two or more outputs 250, 252, 254 may be summed by the power combiner 280 to form a single signal of increased strength, summed output 255. Additionally, outputs may be summed into a multi-frequency signal. Signal power may be measured at the outputs 250, 252, 254 to help ensure that adequate amplifier resources are being allocated to the input signals. Alternatively, the electronic device receiving the amplified signals may measure the power of the received amplified signals and transmit feedback to the system 200. Signal power measurements may be directed to the input selects 220, 222, 224 for adjustment of signal routing at the switch device 230.

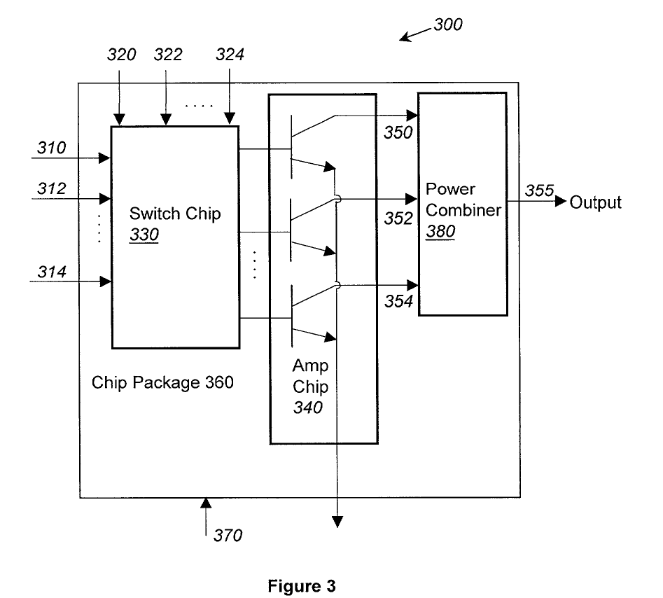

FIG. 3 illustrates an embodiment of a lower level view 300 of the resource managed power amplifier system 200 of FIG. 2. The lower level view 300 is substantially similar to the resource managed power amplifier system 100 described in reference to FIG. 1. The lower level view 300 includes inputs 310, 312, 314, input selects 320, 322, 324, a switch chip 330, amplifier transistor chips 340, 342, 344, outputs 350, 352, 354, power combiner 380, and summed output 355. The subsystems of the lower level view 300 are substantially similar to the corresponding subsystems of the system 100 described above. Preferably, the lower level view 300 is embodied in a chip package 360. Power may be supplied to the lower level view 300 through a power connection 370. Power may also be supplied through an internal power source or battery. The lower level view 300 may be inserted as a component on circuit boards and electrical systems, for example. Preferably, the lower level view 300 is manufactured and enclosed in the chip package 360 with inputs 310, 312, 314 protruding from the chip package 360 and summed output 355 or outputs 350, 352, 354 protruding from the chip package 360. Alternatively, the chip package 360 may have access ports to allow access to the inputs 310, 312, 314 and the outputs 350, 352, 354. In an alternative embodiment, the subsystems of the lower level view 300 may also be manufactured as a single chip.

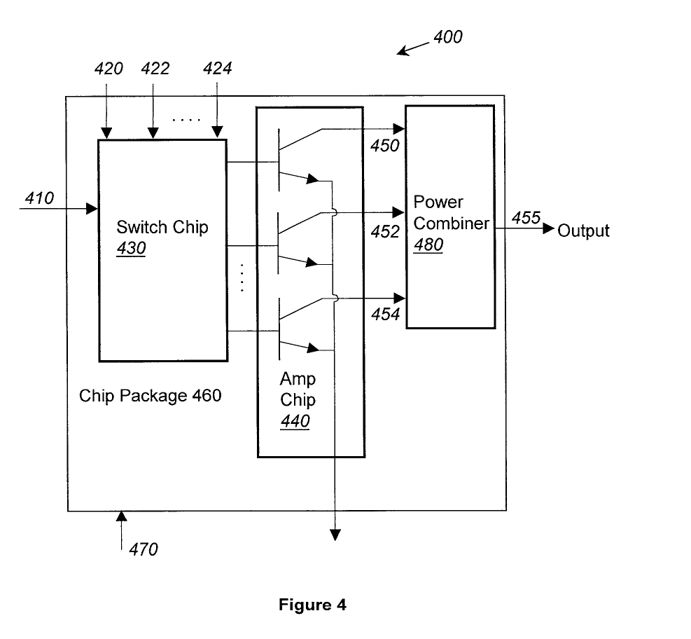

FIG. 4 illustrates another embodiment of a resource managed power amplifier system 400. FIG. 4 may be representative of a system such as a cellular phone, for example. The system 400 is substantially similar to the resource managed power amplifier system 100 described in reference to FIG. 1. The system 400 includes an input 410, output selects 420, 422, 424, a switch chip 430, an amplifier transistor chip 440 including amplifiers 442, 444, 446, outputs 450, 452, 454, power combiner 480, and summed output 455. The subsystems of the system 400 are substantially similar to the corresponding subsystems of the system 100 described above. However, the system 400 includes a single input 410.

Additionally, the output selects 420, 422, 424 select which amplifiers 442-446 or outputs 450, 452, 454 are connected to the input 410 by the switch chip 430. For example, the output selects 420, 422, 424 may connect the input 410 to the first two amplifiers 442, 444 and not the third amplifier 446. The number of amplifiers, as well as which specific amplifiers, that the input 410 is connected to may control the total amplification of the input 410. For example, if amplifiers 442, 444, 446 provide identical amplification, routing the input 410 to two amplifiers provides twice the overall amplification as routing the input 410 to a single amplifier. Additionally, the amplifiers 442, 444, 446 may provide differing levels of amplification. For example, if the amplifier 442 provides three times the amplification of the amplifier 444, the input 410 may be routed to either the amplifier 442 or the amplifier 444 depending upon the amount of amplification desired. One specialized instance in which the amplifiers 442, 444, 446 may provide differing levels of amplification is where the amplifiers 442, 444, 446 provide binary weighted amplification. For example, the amplifier 444 may have twice the number of transistors available that are available in the amplifier 446. The amplifier 442 may have four times the number of transistors used in amplifier 446. Thus, the output power may be adjusted from no (or zero) output to seven times the output of the amplifier 446 in binary stages. The stages of the amplifiers 442, 444, 446 need not be limited to powers of two and may be of any convenient multiple.

For example, a cellular phone produces a signal. Then, the input 410 is connected to a variable number of amplifiers 442-446 and outputs 450, 452, 454 based on the desired output power. The desired output power may depend, for example, on the distance between the cellular phone and the cellular tower. That is, for example, if the cellular phone is close to the cellular tower, the signal path loss is low and the input 410 may be connected to one amplifier 440 for power amplification. Alternatively, for example, if the cellular phone is far away from the cellular tower, the signal path loss is large, and the input 410 may be connected to all amplifiers 442TRW 446 to provide more power amplification. The amplified signals may be summed at the outputs 450, 452, 454 by the power combiner 480 and transmitted as one amplified output signal 455. As described above in related to FIG. 3, the system 400 is preferably enclosed in a chip package 460 with the input 410 and the outputs 450, 452, 454 extending from the chip package 460. The chip package 460 may be connected with a power supply 470 or may have an internal power supply, for example. Alternatively, the chip package 460 may have access ports to allow access to the input 410 and the outputs 456. In an alternative embodiment, the subsystems of the system 400 may also be manufactured as a single chip.

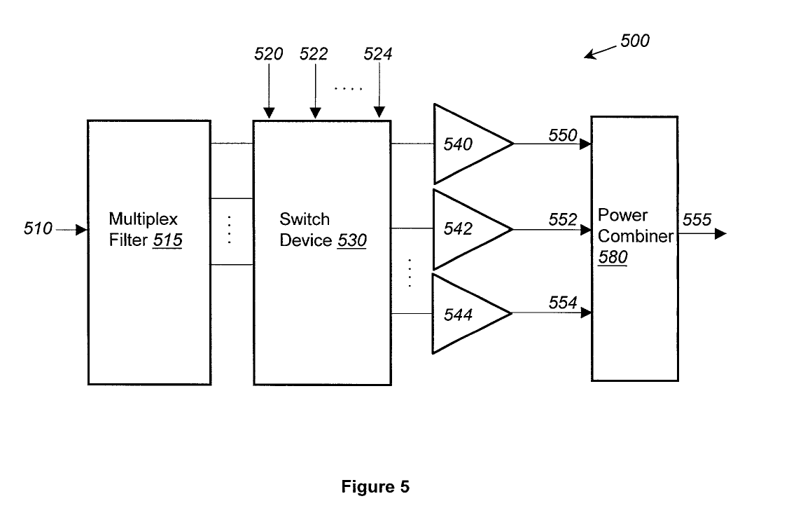

FIG. 5 illustrates another embodiment of a resource managed power amplifier system 500 with the addition of a multiplex filter. The system 500 is substantially similar to the resource managed power amplifier system 100 described in reference to FIG. 1 except the input 510 is filtered as described below. The system 500 includes an input 510, a multiplex filter 515, input selects 520, 522, 524, a switch device 530, amplifiers 540, 542, 544, outputs 550, 552, 554, a power combiner 580 and a summed output 555. The subsystems of the system 500 are substantially similar to the corresponding subsystems of the system 100 described above. However, the system 500 includes the multiplex filter 515.

In operation, the input signal may include more than one communication channel operating over different frequencies, for example. The multiplex filter 515 separates the input signal received at the input 510 into separate signals and feeds the separated signals to the switch device 530. For example, the multiplex filter 515 takes a stream of cellular phone signals and separates the signals by frequency. Then, for example, the separated signals are sent to the switch device 530 for routing to the amplifiers 540, 542, 544 for amplification. The multiplex filter 515 preferably includes a connection to the switch device 530 for each possible input channel, but power is not increased, as unused channels are not active. Each input channel feed to the switch device 530 by the multiplex filter 515 may be routed to one or more amplifiers 540, 542, 544, as described above. The amplified outputs 550554 may be combined at the power combiner 580 or output separately, for example.

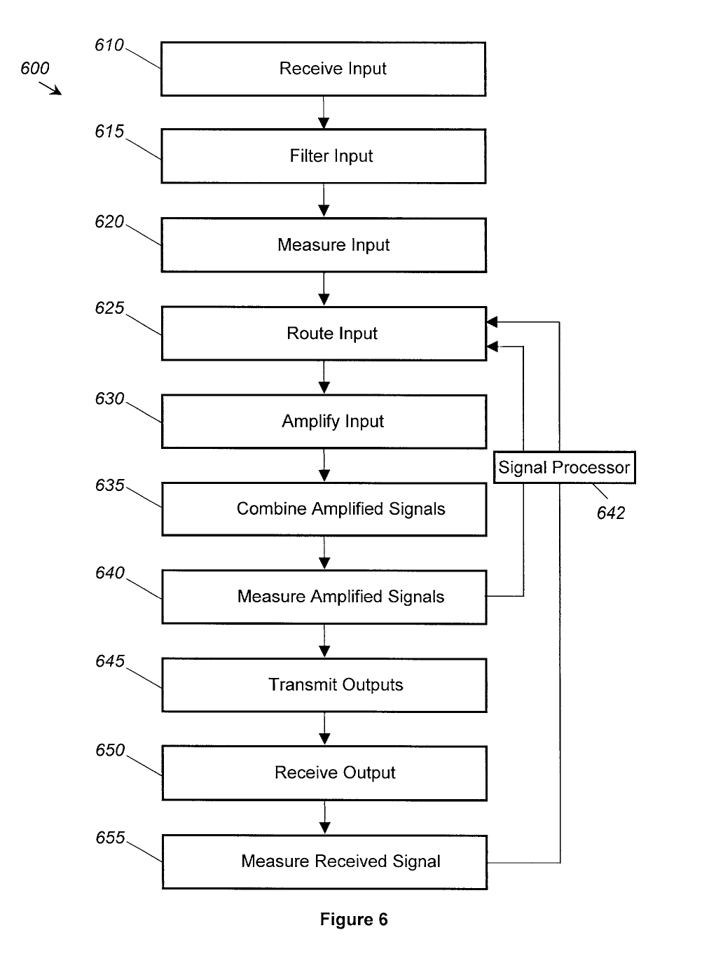

FIG. 6 illustrates a flowchart 600 for dynamically allocating amplification resources in a power amplifier. First, at step 610, input signals are received. For example, cellular phone transmissions are received at a cellular tower. Then, at step 615, if a filter is present and the signal includes a plurality of communication channels at different frequencies, the signal is filtered into separate channels. Next, at step 620, the input signals may be measured to determine the power level of the input signals and the desired amplification. The measurements may be used to calculate amplifier resource allocation.

Then, at step 625, the input signals are routed to amplifier cells. That is, inputs are connected with amplifier cells based on the composition (number of bands and/or power requirements of signals, for example) of the inputs. For example, a computer at a cellular tower analyzes the strengths of the input signals and determines which signals to route to multiple amplifier cells for greater output power and/or which signals to route to single amplifier cells for lesser output power.

Then, at step 630, the input signals are amplified at the amplifier cells. For example, the cellular signals received at the cellular tower pass through power transistors to amplify the power of the cellular signals according to the gain of the power transistors. Next, at step 635, amplified output signals amplified from the same input signal are summed to form one output signal. Additionally, amplified output signals from different input signals may be combined into one signal for transmission. At step 640, the amplified output signal(s) may be measured to determine the power level of the amplified signal(s). The power information may be relayed back through signal processing (step 642) to the switching unit for use in dynamically reconfiguring power amplifier routing and dynamic allocation of amplifier resources.

Then, at step 645, the amplified output signal(s) are transmitted. For example, the amplified signals are transmitted via antennas from the cellular tower to cellular phones and/or other cellular towers. That is, the amplified signals are transmitted, via wireless transmitter, wire transmitter, optical transmitter, or other such connection, for example, to an electronic device for use or further processing, for example.

Next, at step 650, the amplified output signal is received by an electronic device, such as a cellular phone, a cellular phone tower, a satellite, or other such electronic device. Finally, at step 655, the electronic device may measure the power of the received signal and transmit measurement data back to the power amplifier through signal processing (step 642) to adapt to changing power output requirements. For example, routing of input signals to amplifier cells may be reconfigured to achieve a different level of output power. Additionally, more amplifier cells may be dynamically activated to accommodate a greater level of output power. Amplifier cells may also be dynamically deactivated to reduce power consumption and to accommodate a lesser level of power amplification.

Some advantages of the preferred embodiments of the present invention include the following: first, power amplifier resources are dynamically managed to adjust for the current characteristics and/or composition of the input signals. Dynamic management eliminates excess power dissipation wasted on systems where only a low level of output power is needed. That is, traditionally, power amplifiers are designed to provide maximum power at all times. However, the number of users using the system may vary widely. Thus, maximum power is not always needed. Therefore, excess power generated by traditional power amplifiers is wasted. Thus, the preferred embodiments reduce wasted power dissipation through dynamic amplifier configuration to accommodate changes in power output needs.

Second, because the dynamic activation of the amplifier cells results in greater power efficiency in the power amplifier system, battery life or overall power consumption may be improved. For example, more efficient power amplification in a cellular phone may result in longer cellular phone battery life and extended phone talk time. Additionally, dynamic routing of inputs to outputs facilitates scalability and upgradeability of the power amplifier system, as well as redundancy in the event of individual amplifier cell failure. Power efficiency and system redundancy may benefit systems such as satellites, for example, that are expensive to build and repair. Similarly, redundancy and power efficiency may reduce the expense and maintenance of cellular phone towers and base stations, for example.

In addition, the present invention may reduce intermodulation products between users in power amplifiers. That is, traditionally, input signal frequencies from multiple users may mix together and create interference (intermodulation products) which distorts the quality of the amplified signals. The preferred embodiments reduce such intermodulation products by first filtering signals based on time or frequency and then routing individual signals to amplifier resources preventing signal interaction.

While particular elements, embodiments and applications of the present invention have been shown and described, it will be understood that the invention is not limited thereto since modifications may be made by those skilled in the art, particularly in light of the foregoing teachings. It is therefore contemplated by the appended claims to cover such modifications as incorporate those features which come within the spirit and scope of the invention.

What is laimed is:

1. A dynamically configurable signal amplifier, said amplifier comprising:
a switching unit routing a signal to at least one of a plurality of amplifier cells; and
a plurality of amplifier cells for amplifying said signal to produce an amplified signal.

2. The amplifier of claim 1 wherein said switching unit routes said signal based on signal power.

3. The amplifier of claim 1 wherein at least one of said plurality of amplifier cells provides a different amplification from at least one other of said plurality of amplifier cells.

4. The amplifier of claim 3 wherein said at least one of said plurality of amplifier cells is binary weighted with respect to said at least one other of said plurality of amplifier cells.

5. The amplifier of claim 1 further comprising an output for transmitting said amplified signal.

6. The amplifier of claim 5 wherein said output combines a plurality of amplified signals for transmission.

7. The amplifier of claim 5 wherein said output sums a plurality of amplified signals for transmission.

8. The amplifier of claim 1 further comprising a multiplex filter for filtering said signal on the basis of one of time and frequency.

9. A dynamically configurable signal amplifier, said amplifier comprising:
a plurality of amplifier cells for amplifying said signal to produce an amplified signal; and
a switching unit routing a plurality of signals to a plurality of amplifier cells.

10. A dynamically configurable amplifier unit for signal amplification, said unit comprising:
a plurality of amplifier cells for amplifying an input signal, said input signal amplified using a first number of amplifier cells to amplify said input signal to a first power level and said signal amplified using a second number of amplifier cells to amplify said input signal to a second power level.

11. The unit of claim 10 wherein said plurality of amplifier cells is configured in response to an input selector.

12. The unit of claim 11 wherein said plurality of amplified signals are summed to produce an output signal.

13. The unit of claim 10 wherein at least one of said plurality of amplifier cells provides a different amplification from at least one other of said plurality of amplifier cells.

14. The unit of claim 13 wherein said at least one of said plurality of amplifier cells is binary weighted with respect to said at least one other of said plurality of amplifier cells.

15. An adaptable switching unit for signal amplification, said unit comprising:
a plurality of connections for routing an input signal for signal amplification;
at least one input selector controlling said plurality of connections based on an external indicator.

16. The unit of claim 15 wherein said plurality of connections routes a plurality of input signals.

17. The unit of claim 15 further comprising a plurality of input selectors for controlling said plurality of connections.

18. The unit of claim 15 wherein said external indicator comprises desired signal output power.

19. The unit of claim 15 wherein said plurality of connections route said input signal to one of a plurality of amplifier cells for signal amplification.

20. The unit of claim 15 wherein said plurality of connections route said input signal to a plurality of amplifier cells for signal amplification.

21. The unit of claim 19 wherein at least one of said plurality of amplifier cells provides a different amplification from at least one other of said plurality of amplifier cells.

22. The unit of claim 21 wherein said at least one of said plurality of amplifier cells is binary weighted with respect to said at least one other of said plurality of amplifier cells.

23. A method for amplifying a signal, said method comprising: receiving at least one signal;
routing said at least one signal to at least one amplifier according to an input selector; and
amplifying said at least one signal using said amplifier to produce an amplified signal.

24. The method of claim 23 wherein said routing step further comprises routing said signal to an amplifier according to a plurality of input selectors.

25. The method of claim 23 wherein said routing step further comprises routing said signal to a plurality of amplifiers to produce a plurality of amplified signals.

26. The method of claim 25 further comprising the step of summing said plurality of amplified signals.

27. The method of claim 23 further comprising the step of filtering said signal.

28. The method of claim 27 wherein said filtering step further comprises filtering said signal into channels of different frequencies.

29. The method of claim 23 wherein said routing step includes routing said signal to at least one of said plurality of amplifier cells, wherein said at least one of said plurality of amplifier cells provides a different amplification from at least one other of said plurality of amplifier cells.

30. The method of claim 29 wherein said routing step includes routing said signal to at least one of said plurality of amplifier cells, wherein said at least one of said plurality of amplifier cells provides a different amplification from at least one other of said plurality of amplifier cells, and wherein said at least one of said plurality of amplifier cells is binary weighted with respect to said at least one other of said plurality of amplifier cells.
